(19) United States
(12) Patent Application Publication
(10) Pub. No.: US 2017/0287998 A1
(43) Pub. Date: Oct. 5, 2017

(54) ORGANIC EL DISPLAY DEVICE AND METHOD OF MANUFACTURING AN ORGANIC EL DISPLAY DEVICE

(71) Applicant: Japan Display Inc., Minato-ku (JP)

(72) Inventor: Satoshi MARUYAMA, Minato-ku (JP)

(73) Assignee: Japan Display Inc., Minato-ku (JP)

(21) Appl. No.: 15/468,939

(22) Filed: Mar. 24, 2017

(30) Foreign Application Priority Data
Apr. 4, 2016 (JP) 2016-075394

(51) Int. Cl. H01L 27/32; H01L 51/56

(52) U.S. Cl. CPC H01L 27/3262; H01L 51/56; H01L 27/3248

(57) ABSTRACT

An organic EL display device includes a plurality of pixels and a transistor in each of the pixels. The transistor includes a drain electrode and a source electrode. A first gate electrode formed between the source electrode and the drain electrode, and a semiconductor film formed at a lower layer side of the first gate electrode. A first region that is one of a region between the first gate electrode and the drain electrode and a region between the first gate electrode and the source electrode of the semiconductor film has a high density of n-type ions and a second region that is the other one of the region between the first gate electrode and the drain electrode and the region between the first gate electrode and the source electrode of the semiconductor film has a low density of n-type ions.

### CROSS-REFERENCE TO RELATED APPLICATION

The present application claims priority from the Japanese Application JP2016-75394 filed on Apr. 4, 2016, the content of which is hereby incorporated by reference into this application.

### BACKGROUND OF THE INVENTION

### 1. Field of the Invention

The present invention relates to an organic EL display device and a method of manufacturing an organic EL display device.

### 2. Description of the Related Art

Recent years, an organic EL display device using a light emitting element called an organic light emitting diode (OLED) (hereinafter referred to as an organic EL element) is put into a practical use. The organic EL display device controls a current that is made to flow in an organic EL element of each pixel by using a field effect transistor provided in each pixel to thereby perform an image display.

The field effect transistor performs an action of amplifying a current between a source electrode and a drain electrode in accordance with a voltage applied to a gate electrode. However, in a case where a strong electric field is generated near the drain electrode, there occurs a kink phenomenon as below. That is, if a strong electric field is generated near the drain electrode, electrons that flow from the source electrode to the drain electrode are accelerated by the strong electric field, and carriers are generated due to collisions of the accelerated electrons and crystal lattices (an impact ion phenomenon). Due to the carriers, the field effect transistor has a voltage current characteristics including a rapid current change (a kink phenomenon), not only a simple action of amplifying a current.

Now, the kink phenomenon is explained with a reference to FIG. 7. For example, FIG. 7 is a diagram illustrating a voltage current characteristics of the field effect transistor. The horizontal axis indicates a voltage of the gate electrode (Vd), and the vertical axis indicates a current between the source and the drain (Id). As illustrated at a part 700 of FIG. 7, in a case where the kink phenomenon occurs, the field effect transistor has a voltage current characteristics that if the Vd voltage gets higher than a certain voltage, Id rapidly increases.

Further, since a characteristics change of the field effect transistor due to the kink phenomenon widely varies pixel by pixel, there are display defects such as a luminance variation among pixels, a horizontal stripe, and a vertical stripe.

Regarding these problems, Japanese Unexamined Patent Application Publication No. 2014-44439, for example, discloses providing a lightly doped drain region (hereinafter referred to as an LDD region) in which a low density of n-type ions is injected and a heavily doped drain region between two channel regions in a TFT (Thin Film Transistor) including a multi-gate structure and inhibiting an occurrence of the kink phenomenon by moderating a change in the electric field between the drain electrode and the source electrode.

### SUMMARY OF THE INVENTION

As in Japanese Unexamined Patent Application Publication No. 2014-44439, in the configuration where the LDD region and the heavily doped region are adjacent to each other, in the case where a position of a border between the LDD region and the heavily doped region is varied pixel by pixel, the moderating effect of the kink phenomenon varies pixel by pixel, and there is a possibility that the display defects remain.

Further, in order to prevent the variation of a position of a border between the LDD region and the heavily doped region, the configuration to inject a high density of impurities in a region that corresponds to the LDD region of Japanese Unexamined Patent Application Publication No. 2014-44439 is conceivable. However, an increase of a power consumption and a decrease of a luminance possibly occur due to an increase of a resistance of a transistor.

The present invention has been made in view of the above problems, and the object of the present invention is to provide an organic EL display device in which the variation of the transistor characteristics among the pixels is moderated without causing an excessive decrease of the luminance and an increase of the power consumption and to provide a manufacturing method of such an organic EL display device.

According to one aspect of the present invention, an organic EL display device includes a plurality of pixels and a transistor that controls a current that is made to flow in an organic EL element in each of the pixels. The transistor includes a drain electrode and a source electrode, one of which is electrically connected to the organic EL element and to the other one of which an electric power is supplied from an outside of the organic EL display device, a first gate electrode formed between the source electrode and the drain electrode, and a semiconductor film formed at a lower layer side of the first gate electrode. A first region that is one of a region between the first gate electrode and the drain electrode and a region between the first gate electrode and the source electrode of the semiconductor film has a high density of n-type ions and a second region that is the other one of the region between the first gate electrode and the drain electrode and the region between the first gate electrode and the source electrode of the semiconductor film has a low density of n-type ions.

In one embodiment of the present invention, the first region has a high density of n-type ions all over the first region, and the second region has a low density of n-type ions all over the second region.

In one embodiment of the present invention, the transistor is provided with a second gate electrode on the first gate electrode with an intervention of an insulating layer, and includes a region that overlaps with the first gate electrode in a planar view in at least a part of the first region.

In one embodiment of the present invention, the second gate electrode is configured to include a region that overlaps with the first region from among the first region and the second region in a planar view, and to not include a region that overlaps with the second region.

According to another aspect of the present invention, a method of manufacturing an organic EL display device comprising a plurality of pixels and a transistor that controls a current that is made to flow in an organic EL element in each of the pixels, includes steps of forming a semiconductor film included in the transistor, forming a first gate electrode on an upper layer side of the semiconductor film at a central part of the semiconductor film, injecting n-type ions in the semiconductor film using the first gate electrode as a mask, forming an insulating film so as to cover the semiconductor film and the first gate electrode, forming a second gate electrode on an upper layer side of the insulating film so as to overlap with only one of a region between the first gate electrode and the drain electrode and a region between the first gate electrode and the source electrode of the semiconductor film, and injecting n-type ions in the semiconductor film using the second gate electrode as a mask.

### BRIEF DESCRIPTION OF THE DRAWINGS

FIG. 1 is a view schematically illustrating an organic EL display device according to an embodiment of the present invention.

FIG. 2 is a view schematically illustrating an organic EL panel.

FIG. 3 is a view schematically illustrating a pixel and a control circuit.

FIG. 4 is a planar view illustrating a driving transistor.

FIG. 5 is a view illustrating a cross section of a TFT substrate, taken in the vicinity of the driving transistor.

FIG. 6 is a flowchart illustrating a manufacturing method of the organic EL display device.

FIG. 7 is a diagram illustrating the kink phenomenon.

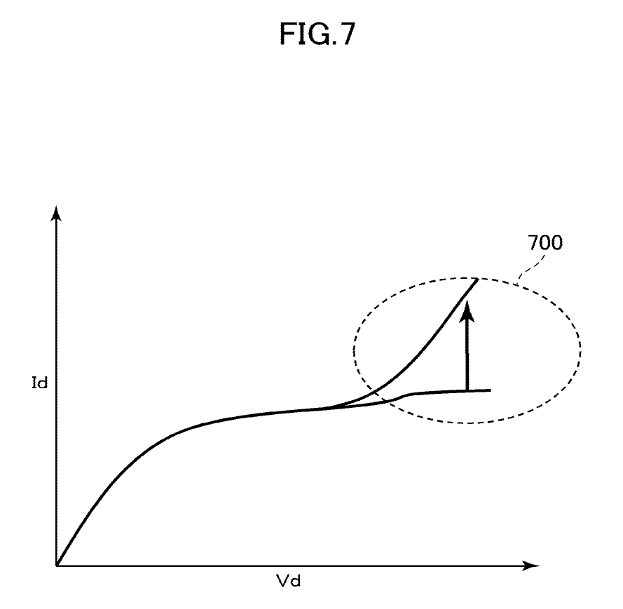

### DETAILED DESCRIPTION OF THE INVENTION

Below, respective embodiments of the present invention are explained with reference to the accompanying drawings. The disclosed embodiments are merely examples, and appropriate variations within the spirit of the present invention that can be easily arrived at by those skilled in the art are naturally included in the scope of the present invention. Further, while the width, thickness, shape, and the like of each part in the drawings may be illustrated schematically as compared with the actual embodiments in order to clarify the explanation, these are merely examples and an interpretation of the present invention should not be limited thereto. Furthermore, in the specification and respective drawings, the same reference symbols may be applied to elements similar to those that have already been illustrated in another drawing and a detailed explanation of such elements may be omitted as appropriate.

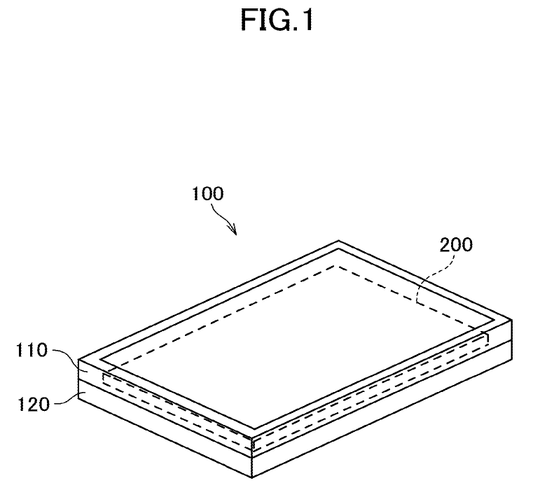

FIG. 1 is a view schematically illustrating an organic EL display device 100 according to an embodiment of the present invention. As illustrated in the figure, the organic EL display device 100 is composed of an organic EL panel 200 fixed so as to be sandwiched by an upper frame 110 and a lower frame 120.

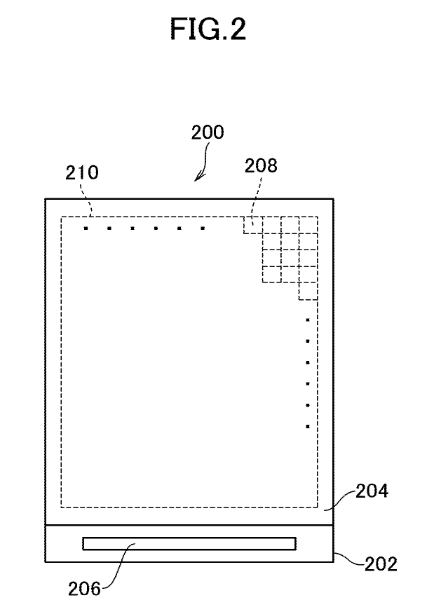

FIG. 2 is a view illustrating a configuration of the organic EL panel 200 of FIG. 1. The organic EL panel 200 includes a TFT (Thin Film Transistor) substrate 202, a protecting film 204, and a driving IC (Integrated Circuit) 206.

The TFT substrate 202 includes a plurality of pixels 208 arranged in a matrix in a display region 210. Specifically, for example, the TFT substrate 202 includes a plurality of pixels 208 that emit lights of three or four wavelength regions that are different from one another. Each pixel 208 includes a light emitting layer 518 formed with an organic EL element, and a driving transistor 300 that controls a current that is made to flow in the light emitting layer 518. The light emitting layer 518 and the driving transistor 300 will be described later. The protecting film 204 is a film that protects the TFT substrate 202, and is bonded to the TFT substrate 202 so as to cover a surface of the display region 210 with an adhesive.

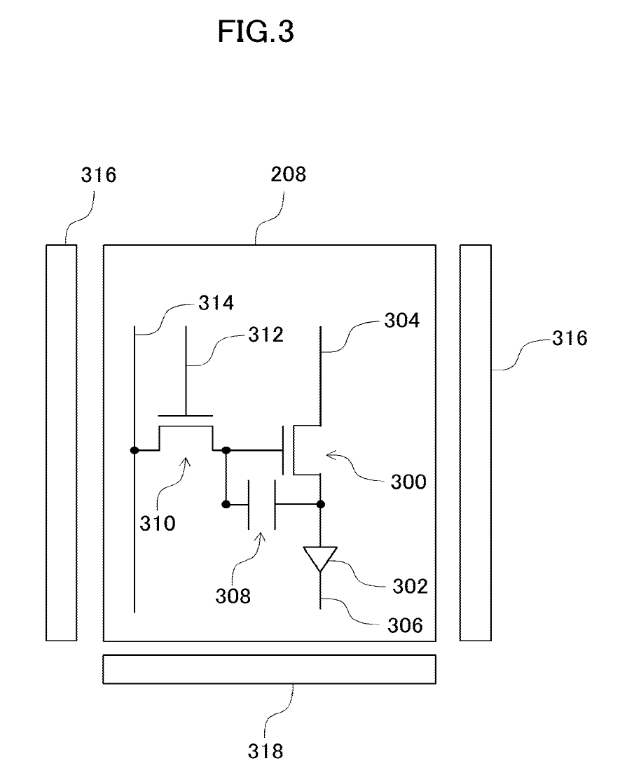

The driving IC 206 displays an image in the display region 210 by controlling a luminance of the respective pixels 208. Specifically, for example, The driving IC 206 controls a current that is made to flow in the driving transistor 300 provided in each pixel 208 as illustrated in FIG. 3 to thereby display an image in the display region 210.

Subsequently, a control circuit that controls the pixels 208, a point in time at which the pixels 208 emit light and a luminance with which the pixels 208 emit light is explained. As illustrated in FIG. 3, the pixel 208 includes the driving transistor 300, a light emitting diode 302, a power source wiring 304, a cathode wiring 306, a capacitor 308, a timing control transistor 310, a timing control wiring 312, and a gradation signal wiring 314. Moreover, the organic EL panel 200 includes a timing control circuit 316. Further, the driving IC 206 includes a gradation control circuit 318.

The driving transistor 300 controls a current that is made to flow in the light emitting diode 302. Specifically, the driving transistor 300 controls a magnitude of the current that is made to flow in the light emitting diode 302 in accordance with a voltage that the capacitor 308 holds, to thereby control a luminance of light that the light emitting diode 302 emits.

The light emitting diode 302 emits light, caused by a flow of the current from an anode terminal to a cathode terminal in the light emitting diode 302. Specifically, the current controlled by the driving transistor 300 flows from the anode terminal to the cathode terminal, and this makes the light emitting diode 302 emit light with an intensity in accordance with a magnitude of the current. Note that the light emitting diode 302 is composed of the light emitting layer 518 to be described later.

The power source wiring 304 provides a power source to the driving transistor 300. Specifically, the power source wiring 304 is electrically connected to one of a source electrode 402 or a drain electrode 404 of the driving transistor 300. Further, the power source wiring 304 provides a power source to the source electrode 402 or the drain electrode 404 of the driving transistor 300 for driving the driving transistor 300.

The cathode wiring 306 is electrically connected to the cathode terminal of the light emitting diode 302. Note that the cathode wiring 306 is electrically connected to the cathode electrode 520 to be described later.

The capacitor 308 holds a voltage in accordance with a magnitude of the current that is made to flow in the light emitting diode 302. Specifically, the capacitor 308 holds a voltage supplied by the gradation signal wiring 314 via the timing control transistor 310.

The timing control transistor 310 controls a point in time to change the voltage that the capacitor 308 holds. Specifically, the timing control transistor 310 supplies a voltage of the gradation signal wiring 314 to the capacitor 308 based on a signal supplied to the gate terminal of the timing control transistor 310.

The timing control wiring 312 is electrically connected to the gate terminal of the timing control transistor 310, and supplies the gate terminal of the timing control transistor 310 with a signal supplied from the timing control circuit 316.

The gradation signal wiring 314 is electrically connected to the source terminal or the drain terminal of the timing control transistor 310. Further, the gradation signal wiring 314 supplies, via the timing control transistor 310, the capacitor 308 with a voltage supplied from the gradation control circuit 318.

The timing control circuit 316 controls a point in time at which the light emitting diode 302 of respective pixels 208 emit light. Specifically, the timing control circuit 316 generates a signal to control a point in time at which the light emitting diode 302 of respective pixels 208 emit light, and supplies the signal to the timing control wiring 312 of the respective pixels 208. Note that the timing control circuit 316 may be formed on the substrate 500 included in the TFT substrate 202, and may be formed inside the driving IC 206.

The gradation control circuit 318 controls a luminance of light emitted by the light emitting diode 302 included in the respective pixels 208. Specifically, the gradation control circuit 318 generates a voltage in accordance with a luminance of the respective pixels 208 based on a display image supplied from the outside of the organic EL display device 100, and supplies the voltage to the gradation signal wiring 314 of the respective pixels 208. Note that the gradation control circuit 318 is formed inside the driving IC 206.

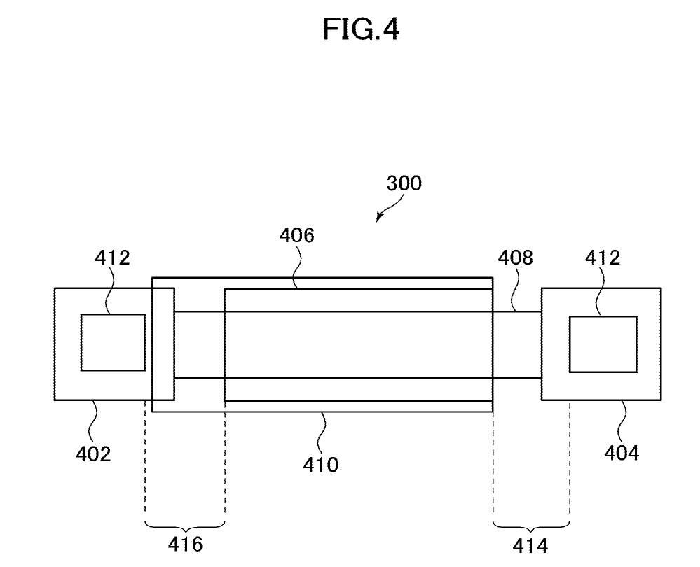

Subsequently, the driving transistor 300 is explained. FIG. 4 is a planar view schematically illustrating the driving transistor 300 provided in the respective pixels 208. As illustrated in FIG. 4, the driving transistor 300 includes the source electrode 402, the drain electrode 404, a first gate electrode 406, a semiconductor film 408, and a second gate electrode 410.

One of the drain electrode 404 and the source electrode 402 is electrically connected to the light emitting layer 518, and a voltage in accordance with an image to be displayed is applied to the other one of them from the outside of the organic EL display device 100. Specifically, for example, the drain electrode 404 is disposed at the right end of the driving transistor 300, and is electrically connected to the light emitting layer 518 via the anode electrode 514 to be described later. The source electrode 402 is disposed at the left side of the driving transistor 300, and a voltage corresponding to a gradation value is applied to the source electrode 402 via the gradation signal wiring 314 by the driving IC 206. Note that the drain electrode 404 and the source electrode 402 may be exchanged with each other.

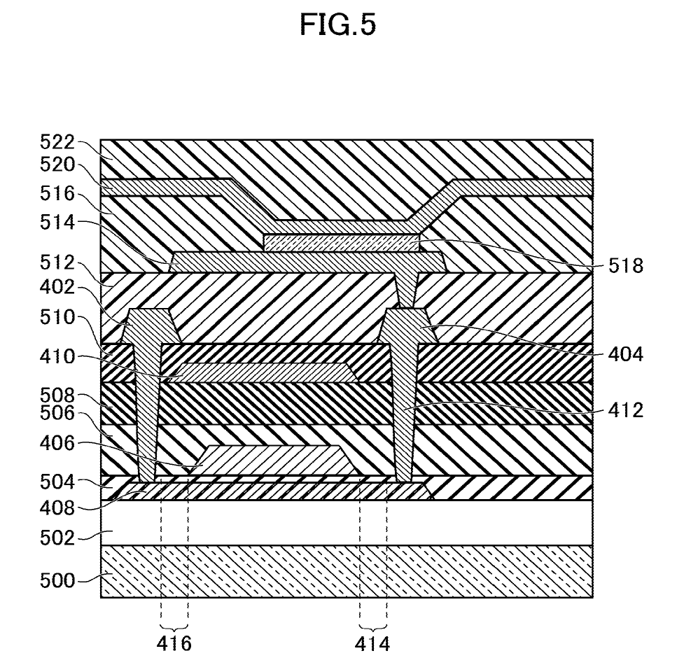

Further, the drain electrode 404 is electrically connected to the semiconductor film 408 via a contact hole 412 formed in a layer between the drain electrode 404 and the semiconductor film 408. Similarly, the source electrode 402 is electrically connected to the semiconductor film 408 via the contact hole 412 formed in a layer between the source electrode 402 and the semiconductor film 408. The contact hole 412 is described later with reference to a cross sectional diagram (FIG. 5).

The first gate electrode 406 is formed between the source electrode 402 and the drain electrode 404. Specifically, for example, the first gate electrode 406 is formed so as to overlap with neither of the source electrode 402 and the drain electrode 404 in a region between the source electrode 402 and the drain electrode in a planar view. Further, the first gate electrode 406 is formed so as to include a region that overlaps with a first region in a planar view at least partially.

The semiconductor film 408 is formed at the lower layer side of the gate electrode. Specifically, the semiconductor film 408 is formed at the lower layer side of the first gate electrode 406, the drain electrode 404 and the source electrode 402 and is formed ranging from a region where the drain electrode 404 is formed to a region where the source electrode 402 is formed.

As to the driving transistor 300, a high density of N-type ions is injected into a first region 414 that is one of the region between the gate electrode and the drain electrode 404 and the region between the gate electrode and the source electrode 402 of the semiconductor film 408, and a low density of n-type ions is injected into a second region that is the other one of the regions.

Specifically, for example, a high density of impurities such as phosphorus (n-type ions) is injected for forming an n-type semiconductor into the semiconductor film 408 that is formed in the first region 414 that is a region between the contact hole 412 for the drain electrode 404 and the first gate electrode 406. Further, n-type ions for forming an n-type semiconductor such as phosphorus are injected with a density lower than that for the first region 414 into the semiconductor film 408 formed in the second region 416 that is a region between the contact hole 412 for the source electrode 402 and the first gate electrode 406.

The second gate electrode 410 is connected to the first gate electrode 406 so as to have the same potential with the first gate electrode 406, and is formed so as to include a region that overlaps in a planar view with the second region 416 out of the first region 414 and the second region 416, but not to include a region that overlaps in a planar view with the first region 414.

Specifically, for example, the second gate electrode 410 is formed ranging from a nearby region of the contact hole 412 formed for the source electrode 402 to the end of the first gate electrode 406 at the drain electrode 404 side. Further, the second gate electrode 410 is formed over the first gate electrode 406 with an intervention of insulating layers.

The effect of moderating the magnitude of the electric field between the source electrode 402 and the drain electrode 404 becomes high and effective in reducing the kink phenomenon in the case where the potential of the second gate electrode 410 is set to be the same with that of the first gate electrode 406, as compared with the case where the second gate 410 is floating, or the case the second gate electrode 410 is not provided.

Further, in the case where the second gate electrode 410 is floating, a variation of potentials among the pixels 208 becomes large and the shield effect cannot be expected.

Note that the end of the second gate electrode 410 at the source electrode 402 side is preferably close to the source electrode 402 to such an extent that the end is not short-circuited with the source electrode 402. Specifically, it is preferable to cover the second region 416 with the second gate electrode 410 as much as possible by disposing the end as close as possible to the source electrode 402. According to such a configuration, the first region 414 gets an injection of a high density of n-type ions all over itself, and the second region 416 gets an injection of a low density of n-type ions all over itself.

Subsequently, a cross section of the TFT substrate 202 taken in the vicinity of the driving transistor 303 is explained with reference to FIG. 5. As illustrated in the figure, the TFT substrate 202 includes a substrate 500, an undercoat film 502, the semiconductor film 408, a gate insulating film 504, the first gate electrode 406, a first interlayer insulating film 506, a second interlayer insulating film 508, the second gate electrode 410, a third interlayer insulating film 510, the drain electrode 404, the source electrode 402, a planarizing film 512, the anode electrode 514, a rib 516, the light emitting layer 518, the cathode electrode 520, and a sealing film 522.

The substrate 500 is formed with, for example, glass or plastic resin. The undercoat film 502 is formed with, for example, an insulating material as a buffer layer of the semiconductor film 408 on the surface of the substrate 500.

The semiconductor film 408 is formed on the undercoat film 502 in the region where the driving transistor 300 is formed. Specifically, the semiconductor film 408 is formed on the undercoat film 502 with a semiconductor material such as amorphous silicon between the region where the drain electrode 404 is formed and the region where the source electrode 402 is formed. Further, the semiconductor film 408 gets an injection of a high density of n-type ions in the first region 414, and gets an injection of a low density of n-type ions in the first region 416.

The gate insulating film 504 is formed so as to cover the semiconductor film 408 with, for example, SiO. The first gate electrode 406 is an upper layer of the gate insulating film 504, and is formed so as to overlap with a part of the region where the semiconductor film 408 is formed.

The first interlayer insulating film 506 is formed so as to cover the first gate electrode 406 with, for example, SiN. The second interlayer insulating film 508 is formed on the first interlayer insulating film 506 with, for example, SiO.

The second gate electrode 410 is formed on the second interlayer insulating film 508. Specifically, for example, the second gate electrode 410 is an upper layer of the second interlayer insulating film 508, and is formed so as to overlap with the first gate electrode 406 and the second region 416. Here, the end of the second gate electrode 410 at the source electrode 402 side is preferably close to the source electrode 402 to such an extent that the end is not short-circuited with the source electrode 402. Further, it is sufficient that the end of the second gate electrode 410 at the drain electrode 404 side overlaps with the first gate electrode 406, and it may be configured that as illustrate in FIG. 5 this end is not formed at the same position as the end of the first gate electrode 406.

The third interlayer insulating film 510 is formed so as to cover the second gate electrode 410 with, for example, SiO.

The drain electrode 404 is formed on the third interlayer insulating film 510. Specifically, for example, the drain electrode 404 is an upper layer of the third interlayer insulating film 510, and is formed so as to overlap with the end of the semiconductor film 408 at the right side on the figure. Further, the drain electrode 404 is electrically connected to the semiconductor film 408 via the contact hole 412 provided in the layers formed between the drain electrode 404 and the semiconductor film 408.

The source electrode 402 is formed on the third interlayer insulating film 510. Specifically, for example, the source electrode 402 is an upper layer of the third interlayer insulating film 510, and is formed so as to overlap with the end of the semiconductor film 408 at the left side on the figure. Further, the source electrode 402 is electrically connected to the semiconductor film 408 via the contact hole 412 provided in the layers formed between the source electrode 402 and the semiconductor film 408.

The planarizing film 512 is formed so as to cover the drain electrode 404 and the source electrode 402. Specifically, the planarizing film 512 is formed so as to cover the drain electrode 404, the source electrode 402, and the third interlayer insulating film 510 formed under the drain electrode 404 and the source electrode 402, and planarizes a bump due to the layers formed under the planarizing film 512.

The anode electrode 514 is formed on the planarizing film 512. Specifically, the anode electrode 514 is formed on the planarizing film 512, and is electrically connected to the drain electrode 404 via the contact hole provided on the planarizing film 512.

The rib 516 is formed so as to cover a peripheral part of the anode electrode 514. Short-circuiting of the anode electrode 514 and the cathode electrode 520 can be prevented due to this rib 516.

The light emitting layer 518 is formed on the anode electrode 514. Specifically, the light emitting layer 518 is formed by laminating a hole injection layer, a hole transportation layer, an organic EL element, an electron injection layer, an electron transportation layer, and an upper electrode. The organic EL element emits light by recombination of holes injected from the anode electrode 514 and electrons injected from the cathode electrode 520. The hole injection layer, the hole transportation layer, the electron injection layer, and the electron transportation layer are the same with those of the conventional arts, an therefore an explanation of them are omitted. In this embodiment, the light emitting layer 518 is formed using materials that emit light of different colors for respective pixels 208.

The cathode electrode 520 is formed on the rib 516 and the light emitting layer 518. Specifically, for example, the cathode electrode 520 is formed with a transparent electrode such as ITO (Indium Tin Oxide) on the rib 516 and the light emitting layer 518, and makes the light emitting layer 518 emit light by making a current flow between the anode 514 and the cathode electrode 520.

The sealing layer 522 is formed on the cathode electrode 520 so as to cover the TFT substrate 202. The sealing film 522 prevents molecules that cause a deterioration of the organic EL element such as moisture to infiltrate into the light emitting layer 518.

As seen above, only one from among regions of the semiconductor film 408, namely, the one at the source electrode 402 side of the first gate electrode 406 and the one at the drain electrode 404 side of the first gate electrode 406, overlaps with the second gate electrode 410, and thus it is configured that the first region 414 and the second region 416 are separated by the first gate electrode 406. Further, by forming the first region 414 and the second region 416 to be separated from each other, and setting one of them to be the LDD region and the other of them to be the heavily doped region, a variation of a position of the border between the LDD region and the heavily doped region can be prevented.

Further, by injecting a high density of n-type ions all over the first region 414 and injecting a low density of n-type ions all over the second region 416, a variation in size of the regions where n-type ions are injected can be prevented in the first region 414 and the second region 416. As such, a variation of a magnitude of the effect of the kink phenomenon at each transistor 300 can be prevented, which enhances the display quality.

Meanwhile, in order to prevent the kink phenomenon, it is conceivable to adopt a technique to increase the length of a channel of the driving transistor 300. However, recent years, along with an enhancement of an image definition of a display device, the driving transistor 300 is continuously narrowed down, and it is difficult to increase the length of the channel. Therefore, the above configuration is particularly useful on a display device of a high image definition.

Further, in the above, it is configured to include the second gate electrode 410, but the configuration is not limited thereto. It is fine to not include the second gate electrode 410 in the driving transistor 300, in the case where the first region 414 and the second region 416 are formed separately, and one of them is made to be the LDD region and the other one is made to be the heavily doped region.

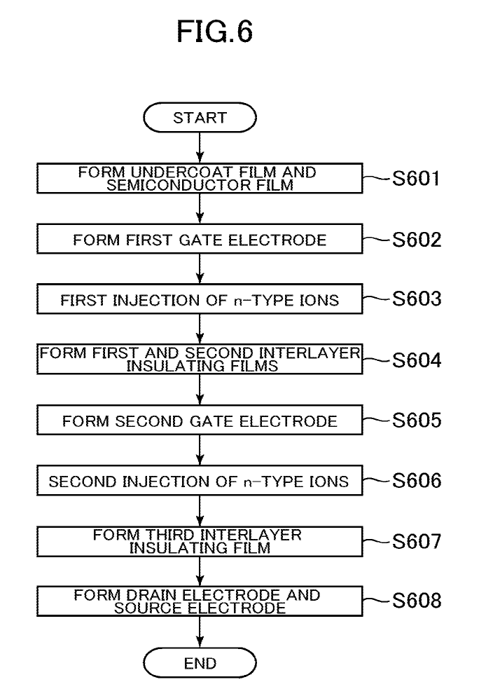

Subsequently, a method of manufacturing the organic EL display device 100 that includes the driving transistor 300 as above. FIG. 6 is a flowchart that illustrates the method of manufacturing. Firstly, the undercoat film 502 is formed so as to cover the substrate 500, and the semiconductor film 408 is formed on the undercoat film 502 (S601). Next, after forming the gate insulating film 504, the first gate electrode 406 is formed to be an upper layer of the gate insulating film 504 and to overlap with a part of the region where the semiconductor film 408 is formed (S602).

Subsequently, the first injection of n-type ions is carried out (S603). Specifically, for example, n-type ions are injected into the semiconductor film 408 using the first gate electrode 406 as a mask. That is, n-type ions are injected into the first region 414 and the second region 416 of the semiconductor film 408. At the point of time where the first injection of n-type ions is completed, the semiconductor film 408 both at the first region 414 and the second region 416 is in a condition where a low density of n-type ions is injected.

Subsequently, the first interlayer insulating film 506 and the second interlayer insulating film 508 are formed so as to cover the first gate electrode 406 and the gate insulating film 504 (S604). And the second gate electrode 410 is formed so as to overlap with the second region 416 only from among the first region 414 and the second region 416 (S605).

Subsequently, the third interlayer insulating film 510 is formed so as to cover the second gate electrode 410 (S607). And at positions corresponding to the both ends of the semiconductor film 408 on the respective layers, from the semiconductor film 408 to the third interlayer insulating film 510, the contact hole 412 is formed and then the drain electrode 404 and the source electrode 402 are formed so as to be electrically connected to the semiconductor film 408 via the contact hole 412 (S608).

Further, in the process of manufacturing the organic EL display device 100, the processes of forming the respective layers, namely, the planarizing film 512 to the sealing film 522 illustrated in FIG. 5, the process of binding the organic EL panel 200 with the upper frame and the lower frame, and the like are included, but such processes are the same with those in the conventional arts. Therefore, a detailed explanation thereof is omitted.

As above, by making the mask used at the first injection of n-type ions and the mask used at the second injection of n-type ions differ from each other, the first region 414 gets two injections of n-type ions, and the second region 416 gets only one injection of n-type ions. According to this process, the first region 414 gets an injection of a high density of n-type ions, and the second region 416 gets an injection of a low density of n-type ions.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device, comprising:
a plurality of pixels; and
a transistor that controls a current that is made to flow in an organic EL element in each of the pixels,
wherein the transistor comprises:
a drain electrode and a source electrode, one of which is electrically connected to the organic EL element and to the other one of which an electric power is supplied from an outside of the organic EL display device;
a first gate electrode formed between the source electrode and the drain electrode; and
a semiconductor film formed at a lower layer side of the first gate electrode, and
a first region that is one of a region between the first gate electrode and the drain electrode and a region between the first gate electrode and the source electrode of the semiconductor film has a high density of n-type ions and a second region that is the other one of the region between the first gate electrode and the drain electrode and the region between the first gate electrode and the source electrode of the semiconductor film has a low density of n-type ions.

2. The organic EL display device according to claim 1,
wherein the first region has a high density of n-type ions all over the first region, and the second region has a low density of n-type ions all over the second region.

3. The organic EL display device according to claim 1,
wherein the transistor is provided with a second gate electrode on the first gate electrode with an intervention of an insulating layer, and includes a region that overlaps with the first gate electrode in a planar view in at least a part of the first region.

4. The organic EL display device according to claim 3,
wherein the second gate electrode is configured to include a region that overlaps with the first region from among the first region and the second region in a planar view, and to not include a region that overlaps with the second region.

5. A method of manufacturing an organic EL display device comprising a plurality of pixels and a transistor that controls a current that is made to flow in an organic EL element in each of the pixels, comprising steps of:
forming a semiconductor film included in the transistor;
forming a first gate electrode on an upper layer side of the semiconductor film at a central part of the semiconductor film;
injecting n-type ions in the semiconductor film using the first gate electrode as a mask;
forming an insulating film so as to cover the semiconductor film and the first gate electrode;
forming a second gate electrode on an upper layer side of the insulating film so as to overlap with only one of a region between the first gate electrode and the drain electrode and a region between the first gate electrode and the source electrode of the semiconductor film; and
injecting n-type ions in the semiconductor film using the second gate electrode as a mask.
